(19) United States
(12) Patent Application Publication
(10) Pub. No.: US 2025/0322130 A1
(43) Pub. Date: Oct. 16, 2025

(54) PERSISTING ERROR INFORMATION BETWEEN INTEGRATED CIRCUIT VERIFICATION CHECKS

(71) Applicant: International Business Machines Corporation, Armonk, NY (US)

(72) Inventors: Michael Alexander Bowen, POUGHKEEPSIE, NY (US); David Wolpert, POUGHKEEPSIE, NY (US); Frank Malgioglio, Hopewell Junction, NY (US); Amanda Christine Venton, Austin, TX (US)

(21) Appl. No.: 18/632,527

(22) Filed: Apr. 11, 2024

(51) Int. Cl. G06F 30/3323; G06F 30/398

(52) U.S. Cl. CPC G06F 30/3323; G06F 30/398

(57) ABSTRACT

A technique of verification for an integrated circuit design under test includes performing a first verification checking run on an integrated circuit design under test (IC DUT) and generating an error report including an error entry for an error detected in the first verification checking run. The error entry associates the error with chip coordinates within the IC DUT. Based on a user input, the error entry of the error report is annotated with user-generated error information. Following an update to the IC DUT, a second verification checking run on the IC DUT is thereafter performed. Following the second verification checking run, the error report is presented, with the user-generated error information persisted between verification checking runs based on the chip coordinates and/or the chip layer of the error.

### BACKGROUND OF THE INVENTION

The present invention relates in general to integrated circuitry, and more specifically, to designing integrated circuitry. Still more particularly, the present invention relates to a technique of persisting error information between integrated circuit verification checks.

Modern processor and system-on-chip designs can include billions of transistors integrated within a semiconductor substrate. To design such large integrated circuits, teams of designers typically employ sophisticated electronic design automation (EDA) tools, which assist the designers in defining, modeling, and verifying the behavior of the overall integrated circuit (or subsets thereof) and developing a physical layout of the integrated circuit chip.

In accordance with one conventional verification process, a verification tool applies a set of design rules to a digital representation of the integrated circuit chip and generates an error report noting violations of the design rules. Currently, various users review the errors listed in the error reports and create their own private notes regarding specific errors for which they have design responsibility. In response to the error report, various users may update the digital representation of the integrated circuit chip and initiate another error checking run of the verification tool to verify the updated design of the integrated circuit chip. This process continues iteratively until all errors are resolved or the chip is submitted to a fabrication facility for production at tape-out or RIT (release interface tape).

### SUMMARY OF THE INVENTION

The present application appreciates that as integrated circuit designs become increasingly complex, it would be useful and desirable to leverage verification tools to improve the efficiency of the design process. For example, it would be useful and desirable to enable error information to be persisted between iterations of a verification checking process and to be conveniently shared among various design teams having responsibility for an integrated circuit design.

In at least one embodiment, a technique of verification for an integrated circuit design under test includes performing a first verification checking run on an integrated circuit design under test (IC DUT) and generating an error report including an error entry for an error detected in the first verification checking run. The error entry associates the error with chip coordinates within the IC DUT. Based on a user input, the error entry of the error report is annotated with user-generated error information. Following an update to the IC DUT, a second verification checking run on the IC DUT is thereafter performed. Following the second verification checking run, the error report is presented, with the user-generated error information persisted between verification checking runs based on the chip coordinates or chip layer of the error.

### BRIEF DESCRIPTION OF THE DRAWINGS

FIG. 1 is a high-level block diagram of an exemplary data processing environment in accordance with one or more embodiments;

FIG. 2 is a high-level block diagram of an exemplary process of verifying an integrated circuit design in accordance with one or more embodiments;

FIGS. 3A-3B illustrate two views of an exemplary integrated circuit design under test in accordance with one or more embodiments; and

FIG. 4 depicts an exemplary graphical user interface through which a verification tool may present an error report in accordance with one or more embodiments.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as verification tool 150. In addition, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and verification tool 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

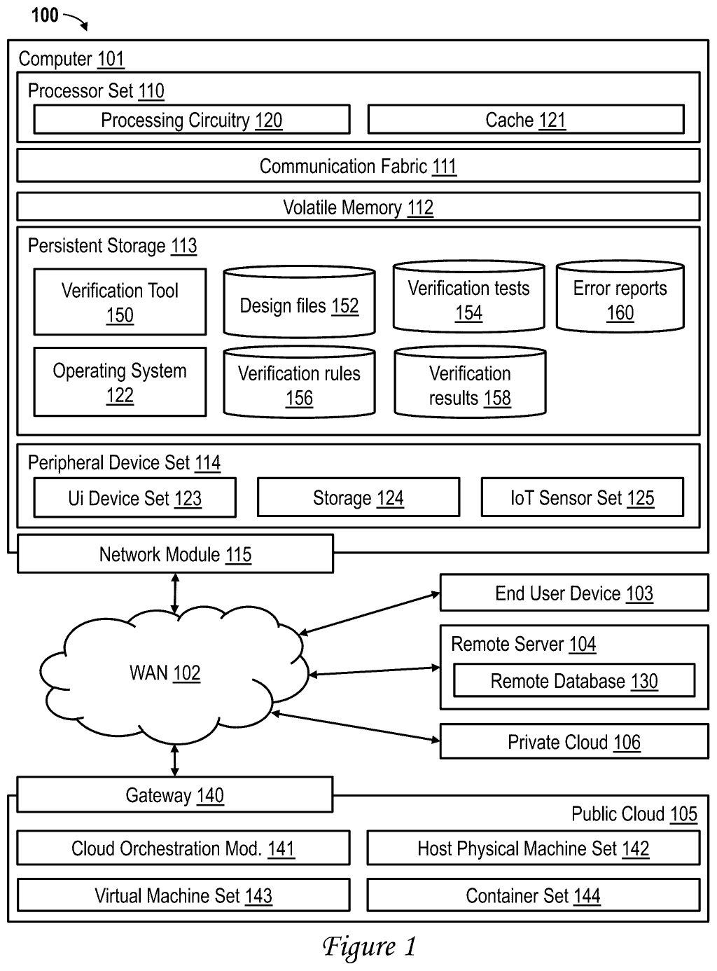

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one or more computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be implemented in verification tool 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet-of-Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the Internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Those of ordinary skill in the art will appreciate that the architecture and components of a data processing environment can vary between embodiments. Accordingly, the exemplary computing environment 100 given in FIG. 1 is not meant to imply architectural limitations with respect to the claimed invention.

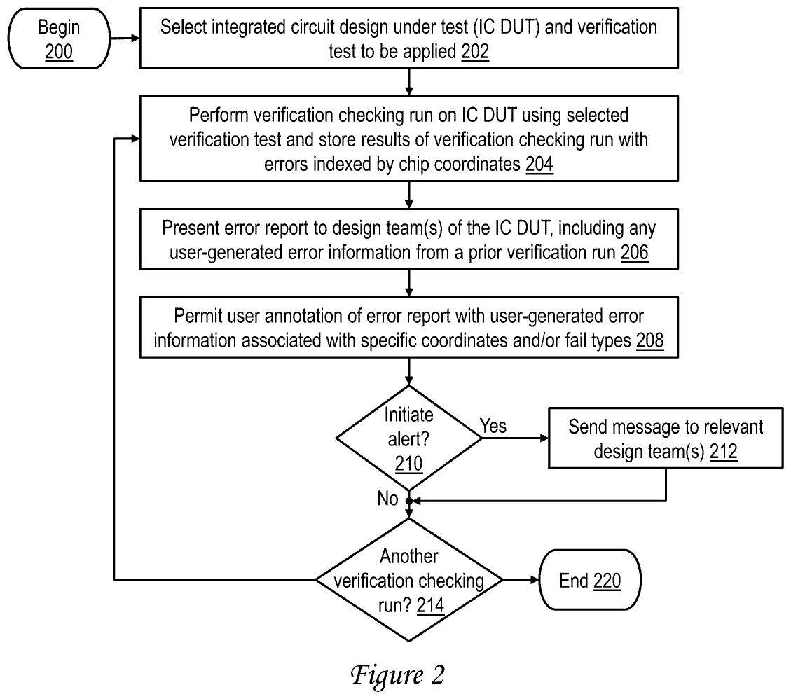

Referring now to FIG. 2, there is depicted a high-level block diagram of an exemplary process of verifying an integrated circuit design in accordance with one or more embodiments. The illustrated process can be performed, for example, by processing circuitry 120 of computer 101 through the execution of verification tool 150.

The process of FIG. 2 begins at block 200 and then proceeds to block 202, which illustrates a user of verification tool 150 utilizing verification tool 150 to select an integrated circuit (IC) design under test (DUT) to be processed. The IC DUT can be defined, for example, by one or more design file 152, which may be stored in persistent storage 113 or elsewhere in computing environment 100. At block 202, the user additionally chooses a selected verification test to be applied to the IC DUT from among a set of one or more verification tests 154. In some embodiments, the selected verification test is a physical design verification test, which performs various checks on the physical layout of an integrated circuit chip based on a set of verification rules 156. In other embodiments, the selected verification test can alternatively or additionally include logical verification of the IC DUT.

At block 204, verification tool 150 performs a verification checking run on the IC DUT using the selected verification test and stores the results of the verification checking run in verification results 158. In a preferred embodiment, any errors reported in verification results 158 are indexed by chip coordinates, that is, by the respective simulated physical locations in the IC design associated with the errors. In various embodiments or use cases, chip coordinates can be specified in two or three dimensions, for example, utilizing X, Y, and Z Cartesian coordinate tuples. In some cases, the Z coordinate may be specified with the identifier of a chip layer. The indexing of verification errors by chip coordinates facilitates verification tool 150 persisting user-generated error information (e.g., tags and/or annotations) between verification checking runs, as discussed further below.

Following at least partial execution of the verification checking run at block 204, verification tool 150 generates and presents an error report 160 accessible to one or more design teams responsible for the development of the IC DUT (block 206). The error report 160, which can include textual and graphical information, can provide general information regarding the verification checking run, such as a timestamp and runtime of the verification checking run, an identifier of the IC DUT, an identifier of a user that initiated the verification checking run, etc. The error report 160 also specifies tool-generated error information provided by verification tool 150, which may specify for each error, for example, an error identifier, an elapsed runtime to error discovery, and chip coordinates of the error. In accordance with one aspect of the disclosed inventions, the error report 160 can additionally include user-generated error information from one or more prior verification checking runs on the IC DUT utilizing the same or different verification test. Thus, if a user annotated or tagged an error reported in a previous verification checking run (e.g., with “Tool error”, “Needs immediate attention”, or “Defer fix until next run”, etc.), verification tool 150 persists that user-generated error information in the newly generated error report based on the error identifier and/or error coordinates.

As indicated at block 208, verification tool 150 permits users to not only view user-generated error information from previous verification checking runs in error report 160, but also to further annotate error report 160 with additional user-generated error information, which verification tool 150 persists between verification checking runs. As noted above, this user-generated error information can include user-generated or predetermined tags or labels, which in some embodiments can include natural language text. Verification tool 150 preferably associates the user-generated error information with particular chip coordinates within the IC DUT and/or with particular error types based on user input. This association enables verification tool 150 to present for viewing and analysis a history of the user-generated error information over time as the IC DUT evolves during the design and verification process. The persistence of user-generated error information between verification checking runs advantageously eliminates the unnecessary repetition of error triage for errors that recur between verification checking runs.

At block 210, verification tool 150 determines whether or not to initiate an alert to one or more design teams based on the contents of the error report 160 and/or the user-generated error information. The determination depicted at block 210 can further include a determination of whether a user has initiated communication of an alert, for example, based on selection of a control in a graphical user interface. Verification tool 150 can also base the determination shown at block 210 on the types and numbers of errors listed in the error report and/or the types, numbers, and/or content of user-generated error information. In response to an affirmative determination at block 210, verification tool 150 issues one or more alert message to one or more possibly geographically distributed design teams, for example, via email, text message, and/or dashboard notifications in verification tool 150 (block 212). The content of the alert messages can provide notification of the types and numbers of errors listed in the error report and/or the types, numbers, and/or content of user-generated error information.

In response to a negative determination at block 210 or following block 212, the process of FIG. 2 proceeds to block 214, which illustrates verification tool 150 determining whether or not to perform another verification checking run for the DUT IC, for example, at some later time after corrective action for one or more of the errors noted in the error report 160 has been taken. In response to verification tool 150 determining at block 214 not to perform another verification checking run, the process of FIG. 2 terminates at block 220; if, however, verification tool 150 makes an affirmative determination at block 214, the process of FIG. 2 returns to block 204 and proceeds iteratively.

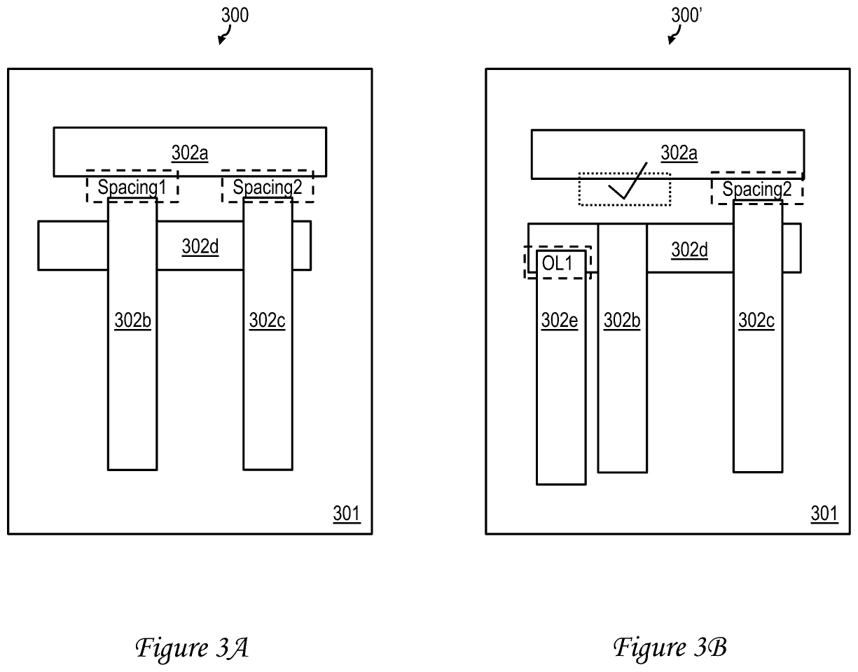

With reference now to FIGS. 3A-3B, there are illustrated two views of an exemplary integrated circuit design under test in accordance with one or more embodiments. In this example, exemplary IC DUT 300 includes a substrate 301 and several circuit features 302a-302d. In this example, verification tool 150 performs physical design verification on IC DUT 300 utilizing a verification test 154 that applies a number of physical verification rules 156 to IC DUT 300. In at least one embodiment, these physical verification rules 156 include at least a spacing rule and an overlap rule that respectively detect errors based on the spacing and overlap of certain circuit features 302a-302d.

FIG. 3A graphically illustrates exemplary errors that may be listed in an error report 160 generated by verification tool 150 as a result of a first verification checking run. In particular, FIG. 3A illustrates that IC DUT 300 includes two spacing errors detected through application of a spacing rule. These spacing errors can be conveniently identified by verification tool 150 in the error report by an error type (e.g., Spacing), error identifier (e.g., 1, 2, . . . , etc.), error coordinates (e.g., {x1, y1, z1} for Spacing1 and {x2, y2, z2} for Spacing2), or error coordinate tuples (e.g., lower-left corner {xll, yll, zll} and upper-right corner {xur, yur, zur} bounding boxes for each error).

Based on the error report presented at block 206 of FIG. 2, a user of verification tool 150 may annotate the error report 160 with user-generated error information as discussed above with reference to block 208 of FIG. 2. For example, the user may annotate error Spacing1 with a tag stating, “This error to be fixed by us,” and may additionally annotate error Spacing2 with a tag stating, “To be fixed by another team in a future release.” As noted above, verification tool 150 preferably associates each of these tags with the respective error type, error identifier, and error coordinates.

Following user annotation of the error report 160, the user and/or others on the design of IC DUT 300 may update design files 152 (e.g., utilizing an unillustrated design tool executing in computing environment 100) to obtain an updated IC DUT 300′ as depicted in FIG. 3B. In exemplary IC DUT 300′, circuit feature 302b has been moved relative to circuit feature 302a, and a new circuit feature 302e overlaying circuit element 302d has been added. Verification tool 150 then performs another verification checking run on IC DUT 300′ and presents an updated error report 160 noting the resolution of error Spacing1, the continued presence of error Spacing2, and the existence of a new overlap error OLI having chip coordinates {x3, y3, z3} due to the overlap between circuit elements 302d and 302e. As described above, verification tool 150 persists the user-generated user information (i.e., “To be fixed by another team in a future release” associated with error Spacing2 to eliminate the repeated triage of this error by the design team(s).

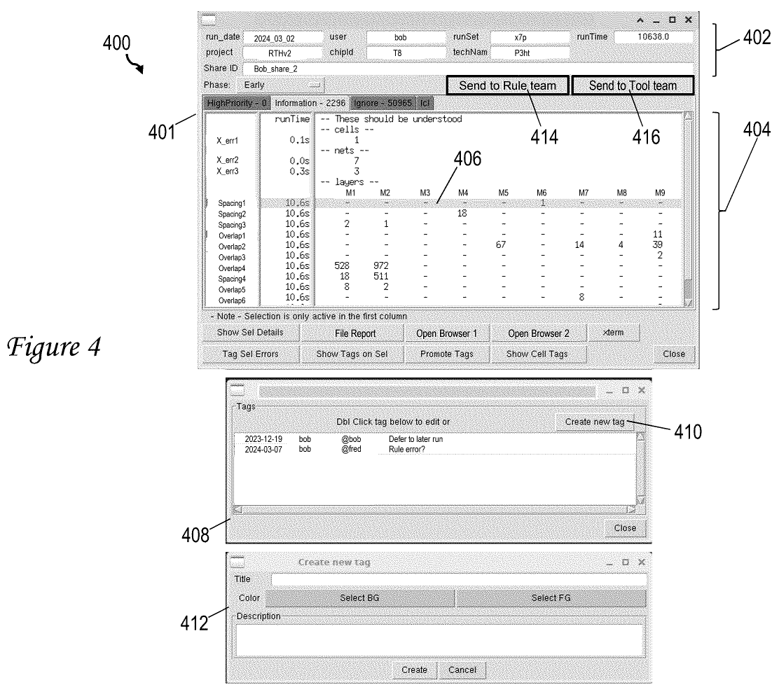

Referring now to FIG. 4, there is depicted an exemplary graphical user interface through which verification tool 150 may present an error report in accordance with one or more embodiments. In this example, verification tool 150 presents an error report 400 (which can be one of error reports 160 collectively illustrated in FIG. 1) via a graphical user interface including a first window 401. First window 401 includes a general information section 402 providing general information regarding the verification checking run and an error listing section 404 listing errors detected in the verification checking run. Error listing section 404 includes an error entry 406, which reports that an error having error identifier Spacing1 occurred in layer M6 of the IC DUT. User selection of error entry 406, for example, utilizing a graphical pointer, invokes additional presentation by verification tool 150 of tag listing window 408, which presents user-generated error information (e.g., tags) associated with the selected error. Each item of user-generated error information displayed in tag listing window 408 can include, for example, a date the tag was entered, an authoring user that entered the tag, a target user (or user group) to be notified about the error (e.g., as indicated by @username), and a natural language text string. In some implementations, verification tool 150 enables the tags presented in tag listing window 408 to be filtered by date, authoring user, target user, and/or other criteria. In the illustrated example, verification tool 150 additionally enables a user to enter a new tag to be associated with the selected error through user selection of button 410, which invokes presentation of tag entry window 412.

In some embodiments, verification tool 150 provides in error report 400 one or more additional 1 facilities for distributing error information (including user-generated error information) to one or more other users. For example, in one implementation, first window 401 includes distribution buttons 414, 416, which, when selected, cause verification tool 150 to distribute error information for a particular error to a particular team involved in the design of the IC DUT. The distributed error information can include, for example, a snapshot of general information 402, one or more errors listed in error listing section 404, and the associated user-generated error information (e.g., tags). Thus, a user may select distribution button 414 to distribute error information to a design team responsible for verification rules 156 in case a selected error is suspected as being erroneous due to a poorly constructed verification rule 156. The user may alternatively or additionally select distribution button 416 to distribute error information to a tool team responsible for development of verification tool 150 in case the error is suspected as being erroneous due to an error in verification tool 150 itself.

As has been described, a technique of verification for an integrated circuit design under test includes performing a first verification checking run on an integrated circuit design under test (IC DUT) and generating an error report including an error entry for an error detected in the first verification checking run. The error entry associates the error with chip coordinates within the IC DUT. Based on a user input, the error entry of the error report is annotated with user-generated error information. Following an update to the IC DUT, a second verification checking run on the IC DUT is thereafter performed. Following the second verification checking run, the error report is presented, with the user-generated error information persisted between verification checking runs based on the chip coordinates or chip layer of the error.

The present invention may be implemented as a method, a system, and/or a computer program product. The computer program product may include a storage device having computer-readable program instructions (program code) thereon for causing a processor to carry out aspects of the present invention. As employed herein, a “storage device” is specifically defined to include only statutory articles of manufacture and to exclude signal media per se, transitory propagating signals per se, and energy per se.

Aspects of the present invention are described herein with reference to flowchart illustrations and/or block diagrams that illustrate the architecture, functionality, and operation of possible implementations of systems, methods, and computer program products according to various embodiments. It will be understood that each block of the block diagrams and/or flowcharts and combinations of blocks in the block diagrams and/or flowcharts can be implemented by special purpose hardware-based systems and/or program code that perform the specified functions. While the present invention has been particularly shown as described with reference to one or more preferred embodiments, it will be understood by those skilled in the art that various changes in form and detail may be made therein without departing from the spirit and scope of the invention.

The figures described above and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms and that multiple of the disclosed embodiments can be combined. Lastly, the use of a singular term, such as, but not limited to, “a” is not intended as limiting of the number of items.

What is claimed is:

1. A method of data processing in a data processing system including a processor, the method comprising:
the processor performing a first verification checking run on an integrated circuit design under test (IC DUT);
the processor generating an error report including an error entry for an error detected in the first verification checking run and associating the error with chip coordinates within the IC DUT;
the processor, based on a user input, annotating the error entry of the error report with user-generated error information;
following an update to the IC DUT, the processor thereafter performing a second verification checking run on the IC DUT; and
the processor presenting the error report following the second verification checking run, wherein the presenting includes persisting the user-generated error information in the error report based on at least one of the following set: the chip coordinates and the chip layer associated with the error.

2. The method of claim 1, wherein the user-generated error information includes a natural language text string.

3. The method of claim 1, further comprising:
the processor alerting at least one user based on content of the user-generated error information.

4. The method of claim 3, wherein the alerting the at least one user includes alerting the at least one user based on inclusion of a username of the user in the user-generated error information.

5. The method of claim 3, wherein the alerting includes alerting the at least one user based on the user-generated error information indicating the error arose from a problem in a rule applied in the first error verification checking run.

6. The method of claim 1, wherein performing the second verification checking run includes performing physical design verification on the integrated circuit design under test (IC DUT).

7. A program product, comprising:
a storage device; and
program code stored within the storage device and executable by processing circuitry of a data processing system to cause the data processing system to perform:
performing a first verification checking run on an integrated circuit design under test (IC DUT);
generating an error report including an error entry for an error detected in the first verification checking run and associating the error with chip coordinates within the IC DUT;
based on a user input, annotating the error entry of the error report with user-generated error information;
following an update to the IC DUT, thereafter performing a second verification checking run on the IC DUT; and
presenting the error report following the second verification checking run, wherein the presenting includes persisting the user-generated error information in the error report based on at least one of the following set: the chip coordinates and the chip layer associated with the error.

8. The program product of claim 7, wherein the user-generated error information includes a natural language text string.

9. The program product of claim 7, wherein the program code further causes the data processing system to perform:
alerting at least one user based on content of the user-generated error information.

10. The program product of claim 9, wherein the alerting the at least one user includes alerting the at least one user based on inclusion of a username of the user in the user-generated error information.

11. The program product of claim 9, wherein the alerting includes alerting the at least one user based on the user-generated error information indicating the error arose from a problem in a rule applied in the first error verification checking run.

12. The program product of claim 7, wherein performing the second verification checking run includes performing physical design verification on the integrated circuit design under test (IC DUT).

13. A data processing system, comprising:
processing circuitry;
a storage device communicatively coupled to the processing circuitry; and
program code stored within the storage device and executable by the processing circuitry of the data processing system to cause the data processing system to perform:
performing a first verification checking run on an integrated circuit design under test (IC DUT);
generating an error report including an error entry for an error detected in the first verification checking run and associating the error with chip coordinates within the IC DUT;
based on a user input, annotating the error entry of the error report with user-generated error information;
following an update to the IC DUT, thereafter performing a second verification checking run on the IC DUT; and
presenting the error report following the second verification checking run, wherein the presenting includes persisting the user-generated error information in the error report based on at least one of the following set: the chip coordinates and the chip layer associated with the error.

14. The data processing system of claim 13, wherein the user-generated error information includes a natural language text string.

15. The data processing system of claim 13, wherein the program code further causes the data processing system to perform:
alerting at least one user based on content of the user-generated error information.

16. The data processing system of claim 15, wherein the alerting the at least one user includes alerting the at least one user based on inclusion of a username of the user in the user-generated error information.

17. The data processing system of claim 15, wherein the alerting includes alerting the at least one user based on the user-generated error information indicating the error arose from a problem in a rule applied in the first error verification checking run.

18. The data processing system of claim 13, wherein performing the second verification checking run includes performing physical design verification on the integrated circuit design under test (IC DUT).
